(19) United States
(12) Patent Application Publication
(10) Pub. No.: US 2026/0202468 A1
(43) Pub. Date: Jul. 16, 2026

(54) IMPROVED VERTICAL PROBE HEAD

(71) Applicant: TECHNOPROBE S.P.A., Cernusco Lombardone (LC) (IT)

(72) Inventor: Stefano FELICI, Cernusco Lombardone (LC) (IT)

(73) Assignee: TECHNOPROBE S.P.A., Cernusco Lombardone (LC) (IT)

(21) Appl. No.: 19/136,467

(22) PCT Filed: Dec. 12, 2023
(86) PCT No.: PCT/EP2023/085306

§ 371 Date: Jun. 6, 2025

(30) Foreign Application Priority Data
Dec. 21, 2022 (IT) 102022000026214

(51) Int. Cl. G01R 31/28; G01R 1/073

(52) U.S. Cl. CPC G01R 31/2891; G01R 1/07342

(57) ABSTRACT

A probe head for testing devices under test integrated on a semiconductor wafer includes a plurality of contact probes having a body extending between first and second ends. The first end contacts contact pads of a device under test and the second end contacts contact Dads and a guide having guide holes housing a portion of the contact probes. The guide lies in a plane wherein the first and second ends of the contact probes are offset from each other and define a scrub direction of the first ends projecting from the guide holes which define abutting points against which corresponding inclined opposite walls of the contact probes abut. The inclined opposite walls deform the contact probes during contact with the device under test and control movement of the portion thereof within the guide holes, and the movement of the first end of the contact probes in the scrub direction.

### FIELD OF APPLICATION

The present invention refers to a probe head comprising a plurality of vertical probes for testing electronic devices integrated on a semiconductor wafer, and the following description is made with reference to this field of application with the sole purpose of simplifying the exposition thereof.

### PRIOR ART

As well known, a probe head is an electronic device adapted to electrically connect a plurality of contact pads of a microstructure, such as an integrated device, with corresponding channels of a measuring equipment which carries out the functionality test thereof, in particular electrical, or generically the test.

The test carried out on integrated electronic devices is in particular useful to detect and isolate defective devices already while being produced. Usually, probe heads are then used for the electrical test of the devices integrated on wafer before cutting and assembling the same inside a chip containment package.

A probe head substantially comprises a plurality of movable contact elements or contact probes held by at least one pair of supports or guides which are substantially plate-shaped and parallel to each other. Said guides are provided with suitable guide holes and are placed at a certain distance from each other so as to leave a free area or an air gap for the movement and the possible deformation of the contact probes, which are slidably housed in said guide holes. In particular, the pair of guides comprises an upper guide and a lower guide, both being provided with guide holes within which the contact probes axially slide, which contact probes are normally made of wires of special alloys with good electrical and mechanical properties.

The good connection between the contact probes and the contact pads of the device under test is guaranteed by the pressure exerted by the probe head on the same device, wherein the contact probes are subjected, during said pressing contact, to a bending inside the air gap between the guides and a sliding inside the respective guide holes. Probes heads of this type are commonly called “vertical probe heads”.

Essentially, the vertical probe heads have an air gap in which a bending of the contact probes occurs, wherein said bending can be assisted by a suitable configuration of the same probes or the guides thereof, as schematically shown in FIG. 1.

In particular, FIG. 1 schematically illustrates a probe head 1 comprising at least one plate-shaped support or upper guide 2, usually indicated as “upper die”, and a plate-shaped support or lower guide 3, usually indicated as “lower die”, having respective guide holes 4 and 5 within which a plurality of contact probes 6 slide.

Each contact probe 6 ends, at an end, with a contact tip 7 which is intended to abut onto a contact pad 8 of a device under test integrated on a wafer 9, so as to carry out the mechanical and electrical contact between said device under test and a testing apparatus (not represented) of which said probe head forms an end element.

Herein and in the following, the term “contact tip” indicates an end area or region of a contact probe intended to contact a contact pad, said end area or region not being necessarily pointed.

In some cases, the contact probes are fixedly constrained to the probe head at the upper plate-shaped support: “blocked” probe heads.

However, probe heads, which are not fixedly blocked but are kept interfaced with a so-called board, possibly by a microcontactor provided with a plurality of contact pads, are more frequently used: they are called “non-blocked” probe heads. The microcontactor is usually called “space transformer” since, in addition to the contact with the probes, it also allows to spatially redistribute the contact pads formed thereon, with respect to the contact pads that are present on the device under test, in particular with a loosening of the distance constraints between the centres of the same pads.

In this case, as illustrated in FIG. 1, each contact probe 6 has a further end area or region which ends with a so-called contact head 7A towards a contact pad 8A of a plurality of contact pads of a space transformer 9A. The good electrical contact between probes 6 and space transformer 9A is ensured by the pressing abutment of the contact heads 7A of the contact probes 6 onto the contact pads 8A of the space transformer 9A which is analogous to the contact of the contact tips 7 with the contact pads 8 of the device under test integrated on the wafer 9.

As indicated in FIG. 1, the upper guide 2 and the lower guide 3 are suitably spaced by an air gap 10 which allows to deform the contact probes 6. Finally, the guide holes 4 and 5 are sized so as to allow the contact probes 6 to slide inside them.

The correct operation of a vertical probe head of the described type is substantially linked to two parameters: the vertical shift, or overtravel, of the contact probes and the horizontal shift, or scrub, of the contact tips of said contact probes on the contact pads of the device under test.

All these features are to be evaluated and calibrated while producing a probe head, as the good electrical connection between probes and device under test must always be guaranteed.

According to a known method, the contact probes 6 are initially produced with a straight shape, with constant transversal section across their entire length, possibly rectangular, and in general thin and possibly pointed at the ends in order to form the contact ends, in particular the contact tip 7 and the contact head 7A, respectively, as illustrated in FIG. 1. Subsequently, the probe head is formed by overlapping the upper guide 2 and the lower guide 3 in order to match the respective guide holes, that is by aligning the respective centres according to a direction which is orthogonal to the guides, by inserting the contact probes 6 in said guide holes, by spacing the upper guide 2 from the lower guide 3 in order to form the air gap 10 and then by shifting said guides, thus causing a deformation of the body of the contact probes 6, in a substantially central position, as illustrated in FIG. 1. In this case, they are probes heads with shifted plates and the contact probes 6 are also indicated as “buckling beam”.

Furthermore, the relative shift of the upper guide 2 and the lower guide 3 determines the deformation direction of the contact probe 6 and therefore the movement direction of the respective contact tip 7 on the contact pad 8 of the device under test integrated on the wafer 9, indicated as scrub direction Dscrub in FIG. 1.

It is also possible to use probes that are already pre-deformed, in which case the shift between the guides accentuates said pre-deformation.

It is also known that, for a vertical probe head with shifted plates, such as the one illustrated in FIG. 1, at the moment of the contact between the contact tips 7 of the contact probes 6 and the contact pads 8 of the device under test integrated on the wafer 9, the deformation of the probes 6 causes a substantially identical bending for all the contact probes 6, so that each contact tip 7 exerts a scrub in the direction Dscrub on the contact pads 8, as indicated by the arrow in FIG. 1.

The simultaneous scrub mechanism of all the contact tips 7 of the plurality of contact probes 6 contained in the probe head 1 on the contact pads 8 of the device under test however generates a lateral force on the wafer 9 (that is parallel to the plane in which said wafer 9 lies), which comprises a plurality of devices under test; in particular, said lateral force is a force acting in the direction Dscrub which is equal to the sum of the forces generated by all the contact probes 6 (all acting in the same direction Dscrub) on all the contact pads 8, whereby said cutting force on the wafer 9 can thus reach high values. In particular, cutting force means a force which is substantially parallel to the wafer 9, which defines a plane that is substantially parallel to the plane in which the guides of the probe head 1 lie, the force being applied at a face thereof facing the probe head 1, which is the face on which the contact pads 8 are formed and onto which the contact tips 7 of the contact probes 6 abut.

Since the probe heads usually comprise a large number of probes, the cutting force due to the scrub of all the contact probes abutting onto the contact pads of the devices under test can be such as to cause a non-negligible lateral shift of the wafer 9 during the pressing contact of the probe head (in particular of the contact probes thereof) on it. This problem is also important in the case of tests of single dies, which do not have the resistance and inertia of an entire semiconductor wafer.

For this reason, it is desirable to be able to control the lateral shift of the contact tips and the deformation of the probe in order to improve the test carried out by the vertical probe heads.

The technical problem of the present invention is to devise a probe head having such functional and structural features as to allow to overcome the limitations and drawbacks which still affect the probe heads made according to the prior art, in particular which are able to simply and efficiently control the movement of the contact tip of the contact probes when contacting the device under test.

### SUMMARY OF THE INVENTION

A first solution idea underlying the present invention is to provide a probe head comprising at least one guide, in particular a lower guide, provided with guide holes which are inclined with respect to the vertical axis, so as to provide fixed abutting points (or abutment points) for corresponding walls of contact probes housed therein and so as to influence (control as desired), through said fixed abutting points, the bending of said contact probes.

Thereby, the movement of the portion of probe in the guide hole is suitably controlled, for example blocked, by the abutment of the probe onto the abutting points in the hole, with limited or absent clearance, therefore controlling, as desired, the scrub of the contact tips of said probes.

However, the possibility of inclining the guide holes with respect to the longitudinal axis of the probes allows a great flexibility and, therefore, in other embodiments, also to enhance the movement of the contact tip of the probes, in particular by creating an opposite inclination with respect to what was previously seen.

In general, the present invention therefore provides inclined guide holes (with a non-vertical axis of symmetry, which is inclined with respect to the guide) thus simply obtaining the fine control of the scrub movement of the contact tips of the contact probes.

Based on said solution idea, the above-mentioned technical problem is solved by a probe head for testing devices under test integrated on a semiconductor wafer, comprising a plurality of contact probes comprising a body which extends along a longitudinal axis between a first end and a second end, the first end being adapted to contact pads of a device under test and the second end being adapted to contact respective contact pads, at least one guide comprising a plurality of guide holes adapted to house a portion of the contact probes inside them, said guide lying in a plane, wherein the first end and the second end of the contact probes are offset from each other, with reference to the longitudinal axis, along an offset direction, thereby defining a scrub direction of said first ends projecting from the respective guide holes, characterized in that the guide comprises guide holes having at least one pair of opposite walls which are inclined (substantially in the same way) with respect to the longitudinal axis, said guide holes thereby having an axis of symmetry which is not perpendicular with respect to the plane of the guide, defining abutting points against which corresponding opposite walls of the contact probes are adapted to abut, said inclined opposite walls being configured to define, by means of the inclination thereof, a deformation of the contact probes during the contact with the device under test and to control the movement of the portion thereof housed within said guide holes, thereby controlling the movement of the first end of the contact probes (in particular in the scrub direction).

More in particular, the invention comprises the following additional and optional features, taken singularly or in combination, if necessary.

According to an aspect of the present invention, the inclined opposite walls can be configured so that, during the contact of the contact probes with the device under test and the bending thereof, the abutting points exert a reaction force which opposes the movement of the portion of the contact probes in the guide holes.

In particular, the opposite walls can be configured to cancel or at least reduce the clearance of the portion of the contact probes in the guide holes, constraining said opposite walls of the contact probes always against the same abutting points.

Alternatively, according to another aspect of the present invention, the inclined opposite walls can be configured so that, during the contact of the contact probes with the device under test and the bending thereof, they are pushed (abutting) towards abutting points which are opposite the abutting points they are close to (onto which they abut) in the rest position.

In particular, the inclined opposite walls can be configured to increase the clearance of the portion of the contact probes in the guide holes and to guide the movement thereof, and thus to increase the scrub movement of the respective first ends.

According to an aspect of the present invention, the inclined opposite walls of the guide holes can substantially be parallel to each other.

According to an aspect of the present invention, the guide can be a lower guide of the probe head and the guide holes thereof can therefore house a lower portion of the contact probes, said lower guide being the guide which is closest to the device under test.

According to an aspect of the present invention, the probe head can further comprise at least one upper guide which is separated from the lower guide by a gap and includes a plurality of guide holes adapted to house at least one corresponding upper portion of the contact probes, wherein the guide holes of the upper guide are shifted with respect to the guide holes of the lower guide in the offset direction, thereby defining the scrub direction of the first ends of the contact probes.

According to an aspect of the present invention, the guide holes of the upper guide can also be provided with opposite walls which are inclined with respect to the longitudinal axis, that is, holes with an axis of symmetry which is not orthogonal to the guide (inclined at a certain angle).

According to an aspect of the present invention, each contact probe can have, before the assembly thereof in the probe head, a non-deformed straight shape, the shift between the guide holes of the lower guide and of the upper guide being apt to cause a deformation of the contact probes resulting in said offset of the ends along the offset direction.

According to an aspect of the present invention, the offset along the offset direction can substantially be equal to 5-30 μm.

According to an aspect of the present invention, the guide can comprise first guide holes, housing a first group of said contact probes, and second guide holes, housing a second group of said contact probes, wherein the first and second guide holes comprise opposite walls which are inclined in a mirror-like manner with respect to the longitudinal axis (for example obtaining respective opposite reaction forces or opposite scrub movements).

According to an aspect of the present invention, the first guide holes can be grouped in at least one first area of the guide, and the second guide holes can be grouped in at least one second area of the guide, wherein the ends of the contact probes of said first group of contact probes in said first area have an opposed scrub with respect to the ends of the contact probes of said second group of contact probes in said second area, forming distinct areas of the probe head with opposite forces on the semiconductor wafer.

The present invention also refers to a probe card for a testing apparatus of electronic devices, comprising at least one probe head as above, a space transformer adapted to perform a space transformation of the distances between contact pads formed on a face thereof facing said probe head, and/or a printed circuit board adapted to interface said probe card with a testing apparatus.

The features and advantages of the probe head according to the invention will become apparent from the description, made herein in the following, of an embodiment example thereof given by way of an indicative and non-limiting example with reference to the attached drawings.

### BRIEF DESCRIPTION OF THE DRAWINGS

In said drawings:

FIG. 1 schematically shows a probe head according to the prior art;

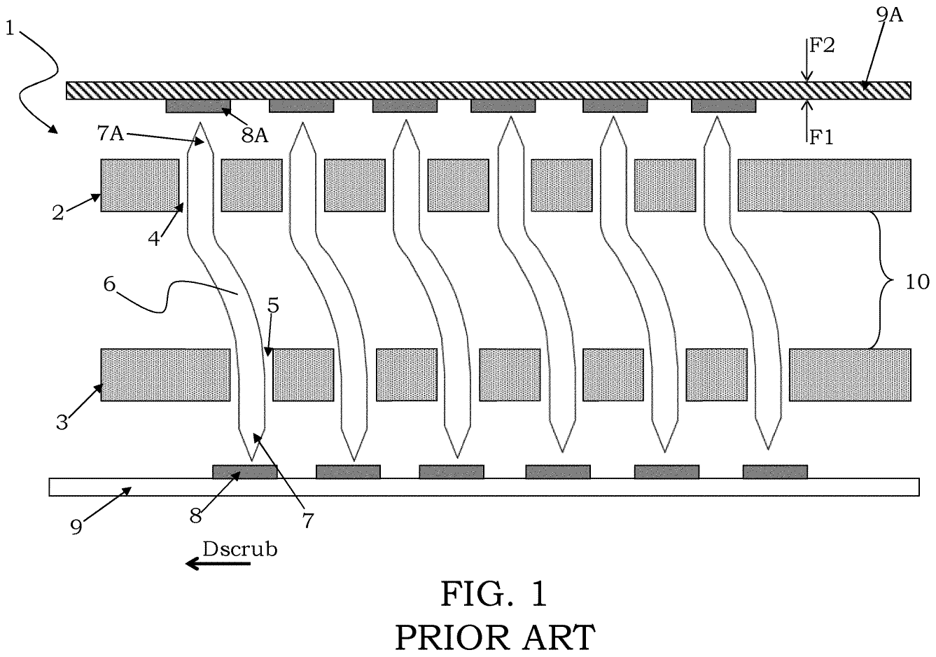

FIG. 2 schematically shows a portion of a probe head according to the present invention;

FIGS. 3A and 3B show a contact probe in different working conditions of the probe head according to embodiments of the present invention;

FIG. 4 schematically shows a probe head according to an embodiment of the present invention; and

FIG. 5 shows a probe head according to another embodiment of the present invention.

### DETAILED DESCRIPTION

With reference to said figures, 20 globally and schematically indicates a vertical probe head for testing electronic devices integrated on a semiconductor wafer, made according to the present invention.

It should be noted that the figures represent schematic views and are not drawn to scale but are instead drawn so as to emphasize the important features of the invention. Furthermore, in the figures, the different elements are represented in a schematic way, their shape can vary depending on the desired application. It should also be noted that, in the figures, identical reference numerals refer to items that are identical in shape or function. Finally, particular features described in relation to an embodiment illustrated in a figure can also be used for the other embodiments illustrated in the other figures.

It should also be noted that, unless explicitly indicated, the process steps can also be reversed if necessary.

The probe head 20 is adapted to connect to an apparatus (which is not illustrated in the figures) to carry out the test of electronic devices integrated on a semiconductor wafer W, wherein the scrub of the respective contact tips is suitably controlled, as detailed in the following description.

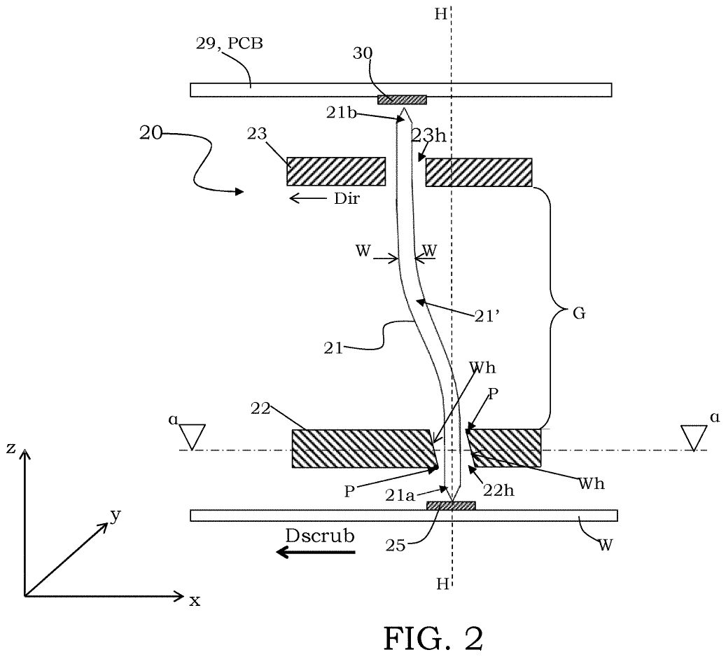

As illustrated in FIG. 2, the probe head 20 of the present invention comprises a plurality of contact probes 21, each being provided with a preferably rod-shaped body 21′ which extends along a longitudinal axis H-H between a first end 21a and a second end 21b, said body 21′ having a deformation as illustrated in more detail in the following.

For simplicity of illustration, only a contact probe 21 is represented in FIG. 2, but the figures are provided by way of non-limiting examples of the scope of the present invention and the number of contact probes can obviously vary according to the needs and circumstances. In general, the probe head 20 can also comprise a very large number of contact probes 21.

The first end 21a of the contact probes 21 is adapted to contact contact pads 25 of a device under test integrated on the semiconductor wafer W and is also indicated in the technical field as “contact tip”, while the second end 21b (also indicated in the sector as “contact head”) can be adapted to contact contact pads 30 of a space transformer 29 or a printed circuit board (also indicated hereinafter as PCB), as well as it can also be welded to an upper support, as will be illustrated in the following. It should be noted that the ends 21a and 21b are not necessarily pointed, their shape can vary according to the needs and/or circumstances.

It should furthermore be noted that the longitudinal axis H-H of the contact probes 21 substantially develops in the direction indicated by the axis z (vertical axis) of the reference system of FIG. 2.

The probe head 20 comprises a lower guide 22 arranged at the first end 21a of the contact probes 21. The lower guide 22 is provided with a plurality of guide holes 22h for slidingly housing the contact probes 21. In other words, the guide 22 is a lower guide of the probe head and the guide holes 22h thereof house a lower portion of the contact probes 21, said lower guide 22 being the guide closest to the device under test DUT.

The lower guide 22 is substantially a plate-shaped support and can have any suitable shape (for example rectangular or squared) in which the longitudinal development axes develop in a plane identified by the axes x and y (horizontal axes) of the reference system of FIG. 2 and orthogonally to the longitudinal development axis H-H of the contact probes 21.

In a preferred embodiment of the present invention, the probe head 20 also comprises an upper guide 23, which is arranged at the second end 21b of the contact probes 21 and is substantially parallel to the lower guide 22, said upper guide 23 being provided with a corresponding plurality of guide holes 23h for slidingly housing the contact probes 21, in particular at least for housing a corresponding upper portion of the contact probes.

As illustrated in FIG. 2, the upper guide 23 is separated from the lower guide 22 by an air gap (or gap) G and is substantially a plate-shaped support having the same shape and extension of said lower guide 22.

In general, according to the present invention, the first end 21a and the second end 21b of the contact probes 21 are offset from each other, with reference to the longitudinal axis H-H, along an offset direction (indicated herein by the arrow “Dir”). Thereby, a deformation of the probes (bending) and a corresponding scrub direction (indicated herein as “Dscrub” and represented in the figures by the respective arrow) of the first ends 21a projecting from the respective guide holes 22h of the lower guide 22 is defined.

For example, as illustrated in the figures, the guide holes 23h of the upper guide 23 can be shifted with respect to the guide holes 22h of the lower guide 22 in the offset direction Dir, thereby defining the scrub direction Dscrub of the first ends 21a of the contact probes 21.

In other words, the lower guide 22 and the upper guide 23 are arranged with respect to each other (in particular offset) so that the first end 21a of each contact probe 21 is offset, with respect to the longitudinal axis H-H, from the second end 21b, that is, so that the contact probes 21, which are preferably straight-shaped, have a deformation of the body 21′. In this embodiment, each contact probe 21 therefore has, before assembling the same in the probe head 20, a non-deformed straight shape, the shift between the guide holes of the upper guide 22 and of the lower guide 23 being apt to cause a deformation of the contact probes 21 resulting in said offset of the ends along the offset direction Dir.

According to less preferred embodiments, it is also possible that the contact probes 21 have an initial pre-deformation and the offset of the guides enhances said pre-deformation. In particular, the offset of the upper and lower guides is related to the offset of the guide holes thereof.

It should be noted that, although the embodiment in which the probe head 20 comprises the upper guide 23 is preferred, also other solutions are possible. By way of example, in a less preferred embodiment, which is not illustrated in the figures, the second end 21b of the contact probes 21 can be welded to a support associated to the probe head 20. In this case, the offset between the ends of the probes is obtained thanks to the suitable shift of the guide holes of the lower guides with respect to the longitudinal axis H-H of the probes.

By way of example only, in general, the offset along the offset direction Dir can substantially be equal to 5-30 μm.

In any case, the offset of the upper and lower guides, that is of the guide holes thereof (and therefore of the ends 21a and 21b of the contact probes 21), determines the desired direction of deformation of said contact probes 21 and, therefore, the movement direction of the respective contact tips 21a on the contact pads 25 of the device under test integrated on the wafer W. In the non-limiting example of FIG. 2, the scrub direction Dscrub is theoretically facing in the negative direction of the axis x, as it happens for the offset direction Dir, due to the specific shape of the contact probe and the distribution of the forces developing therein during the test of the device under test.

The above-mentioned offset of each probe therefore allows to define the scrub of the first ends 21a of the contact probes 21. However, as seen above, said scrub movement determines an overall lateral force on the semiconductor wafer W which can reach extreme values and can cause undesired effects, such as even a shift of the same semiconductor wafer W.

For this reason, advantageously according to the present invention, at least some guide holes 22h of the lower guide 22 comprise at least one pair of opposite walls (indicated with the reference Wh) which are inclined with respect to the longitudinal axis H-H, thereby defining abutting points P against which corresponding opposite walls (indicated with the reference W) of the contact probes 21 are adapted to abut. Suitably, the inclined walls Wh of the guide holes 22h are configured such that, during the contact of the contact probes 21 with the device under test DUT and the bending thereof, the corresponding walls W of said contact probes 21 abut onto said abutting points P, which thereby exert a reaction force F that opposes the movement of said probes in the hole, thereby controlling the movement of the first end 21a of the probes along said scrub direction Dscrub (that is, in this case, substantially blocking the scrub).

Thereby, the presence of the above-mentioned inclined holes allows to more precisely control the deformation to which the contact probes 21 are subjected during the pressing contact with the device under test and allows an optimal control of the scrub movement of the contact tips, thus considerably improving the performances of the probe head 20.

In other words, the movement of the lower portion of the contact probe 21 inside the inclined holes is substantially blocked, without the possibility to reverse the abutting points of the probe thanks to the configuration selected for said guide holes 22h; essentially, during the contact with the testing device, the contact probe 21 pushes on the points P on which it already lays and it does not reverse said abutting points P.

In an embodiment of the present invention, the angle of inclination of the walls of the inclined holes is opposite the scrub outlet angle of the probe, thus obtaining the above-mentioned advantageous technical effect.

As mentioned above, the reaction force exerted by the inclined opposite walls Wh of the guide holes 22 at the abutting points P blocks the movement of the probes in the holes, said inclined opposite walls Wh being actually configured to cancel, or at least significantly reduce, the clearance of the portion of probe in the guide hole 22h, constraining the opposite walls W of the contact probes 21 always against the same abutting points P and thus preventing that, during the overtravel step, the probe changes its abutting point inside the guide hole.

Thereby, it is possible to control the movement of the first ends of each contact probe 21, cancelling (or at least controlling as desired) the scrub movement of said first ends 21a, thus resolving the above-mentioned problem caused by the lateral forces exerted by said probes on the semiconductor wafer W. The abutting points P of the inclined holes are thus adapted to block, or at least reduce in a controlled manner, the scrub movement of the first ends 21a of each contact probe 21, the lateral force exerted by the single probes being applied onto said abutting points P.

It should furthermore be noted that these advantages are also obtained in the presence of a movement of the guide 22 during the test.

As illustrated in the figures, the inclined opposite walls Wh of the guide holes 22h are substantially parallel to each other.

The inclined opposite walls Wh of the guide holes 22h are inclined at an angle which is not limited by particular values, but it is anyway suitable for obtaining the above-mentioned effects.

In an embodiment which is not illustrated in the figures, the guide holes 23h of the upper guide 23 are also provided with opposite walls Wh which are inclined with respect to the longitudinal axis H-H, in order to have an even finer control on the deformation of the contact probe 21. It should furthermore be noted that the present invention is not limited by the number of guides, and therefore, in addition or as an alternative to the already-illustrated guides, also intermediate guides can be present, for which the same considerations can apply.

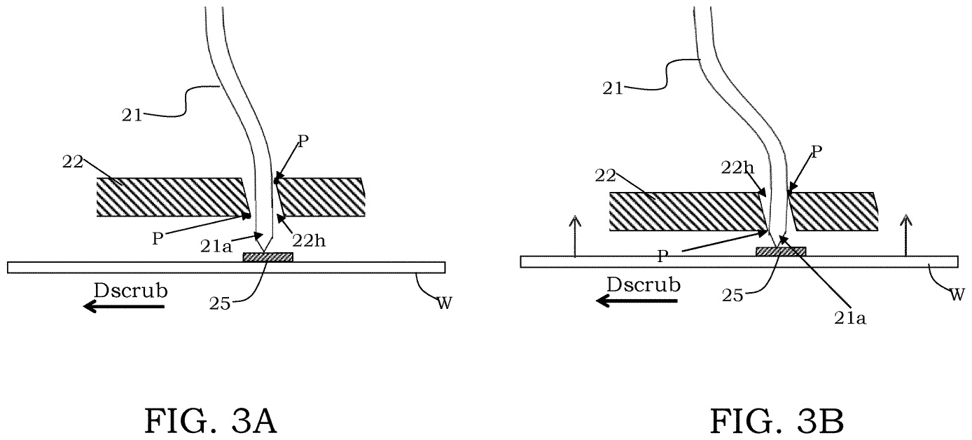

In general, as illustrated in FIGS. 3A and 3B, the contact probes 21 are adapted to bend during the pressing contact with the contact pads 25 of the device under test (as illustrated in FIG. 3B, which shows the probe in the overtravel step, while FIG. 3A shows the probe in the rest conditions) and, in the absence of the inclined hole, there would therefore be a considerable scrub movement of the first ends 21a of the contact probes 21, and said movement would not be controlled in any way.

Suitably, according to the present invention, a first wall of the contact probes 21 is adapted to contact a corresponding first wall of the guide holes 22h at a first abutting point, which is therefore configured to counteract the transversal force exerted by said probes by exerting an opposite reaction force. Furthermore, a second wall of the contact probe 21, which is opposite to the first wall, is in contact with a corresponding second wall of the guide hole at a second abutting point. As mentioned above, if the guide hole were not inclined, a clearance would be defined between the first wall of the contact probe 21 and the first wall of the guide hole. The extent of this clearance would be determined by the size of the guide holes with respect to a diameter of the contact probe 21, which is to be intended, herein and below, as the maximum transversal size, also in the case of sectionally non-circular probes. It should be noted that the first wall of the contact probe 21 (as well as the first wall of the holes) is a wall which follows the longitudinal development axis H-H of the same probe with respect to the scrub direction Dscrub, while the second wall of the contact probe 21 (as well as the second wall of the holes) is a wall which precedes said longitudinal axis H-H in the scrub direction Dscrub.

It should furthermore be noted that a clearance could anyway remain between the walls of the probes and the walls of the holes of the guides, which is anyway considerably reduced by the inclined holes.

The configuration of the present invention therefore limits the negative effects of the lateral force exerted onto the semiconductor wafer W by the contact probes 21. Suitably, this advantage of the probe head 20 according to the present invention is obtained together with the possibility of not modifying the pitch of the guide holes and thus of the contact probes.

As mentioned above, thanks to the presence of the inclined holes, the movement of the probe inside the hole is limited, since the probe cannot change the abutting points P. Thereby, the deformation (bending) of the contact probe 21 is mechanically controlled and the scrub is greatly reduced. There could however be a residual scrub, due to a residual clearance of the contact probe 21 in the guide hole 22h (the holes can possibly be sized to allow this residual scrub). If, on the one hand, this residual scrub is positive since it contributes to the removal of the impurities from the contact pads, on the other hand, due to the presence of many contact probes in some applications, the above-mentioned lateral force is generated, which can cause problems during the test (said force being anyway greatly reduced with respect to the known solutions).

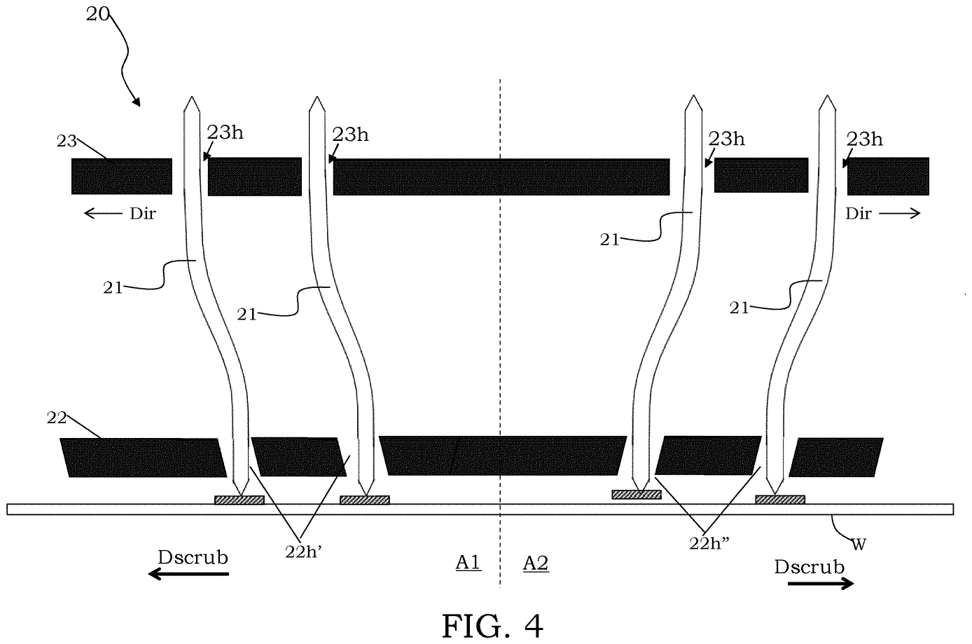

For this reason, in an embodiment of the present invention, the lower guide 22 comprises groups of guide holes which are differently inclined with respect to each other, in particular, it comprises first guide holes 22h′, housing a first group of contact probes 21, and second guide holes 22h″, housing a second group of said contact probes 21, as schematically illustrated in FIG. 4. The offset of the ends of the probes of the first group is opposite with respect to the offset of the probes of the second group, thus resulting in mirror-like deformations and therefore mirror-like scrubs. Suitably, the first and second guide holes have opposite walls which are inclined in a mirror-like manner with respect to the longitudinal axis H-H (that is the holes are inclined in a mirror-like manner), thereby obtaining respective opposite reaction forces, the resultant of all the scrubs being substantially zero.

In this embodiment, the first guide holes 22h′ are grouped in at least one first area A1 of the lower guide 22, while the second guide holes 22h″ are grouped in at least one second area A2 of said lower guide 22. As mentioned above, the ends of the contact probes of the first group of probes in the first area A1 have an opposed scrub with respect to the ends of the probes of the second group of probes in the second area A2, thus forming different areas of the probe head 20 with opposite forces on the semiconductor wafer W, in particular two macro-areas with opposed scrub, so that the scrub in an area is compensated by the scrub in another area, the resulting lateral force being substantially zero.

The above refers to a case in which the inclination of the guide holes is such that the scrub movement is reduced, if not completely cancelled, for the single contact probes of the probe head 20.

It should however be noted that the general teaching of the present description is to provide the guide 22 with at least some inclined holes, that is with the axis of symmetry which develops non-orthogonally with respect to a plane a in which said guide 22 lies, so as to be able to control the scrub movement as desired.

There may be situations in which the scrub is desirable, for example when the problem of the movement of the wafer is not present, said scrub causing the removal of impurities from the pads.

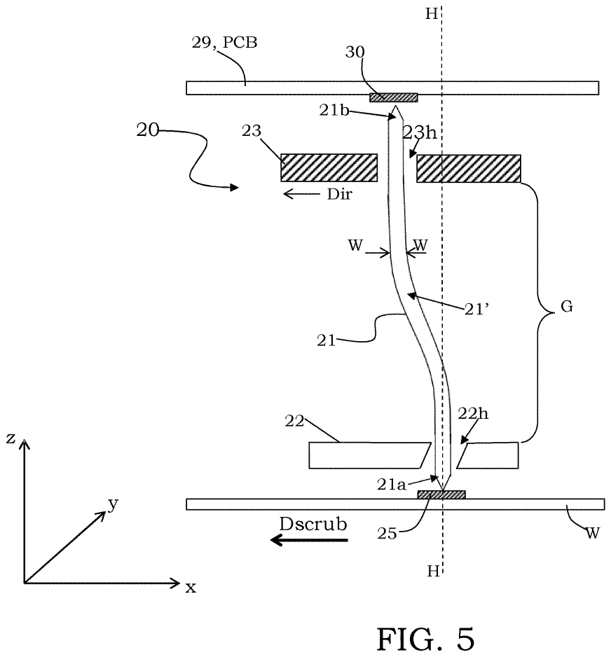

In the embodiment illustrated in FIG. 5, all the aspects discussed above still apply, except the fact the opposite walls of the holes are inclined in an opposite way (that is the inclination of the holes is opposite, the axis of symmetry being mirror-like with respect to the previous condition).

In particular, the inclined opposite walls are configured so that, during the contact of the contact probes 21 with the device under test DUT and the bending thereof, they are pushed towards abutting points which are opposite to the abutting points they are close to in the rest position.

Thereby, the inclined opposite walls Wh are configured to increase the clearance of the portion of the contact probes 21 in the guide holes 22h and to guide the movement thereof, and therefore to increase the scrub movement of the respective first ends 21a.

Also in this case it is possible to provide an embodiment which is similar to the embodiment of FIG. 4, with the necessary modifications, in which the scrub of the two groups of probes has a resultant which is zero, with the advantage that, on the one hand, the scrub of the single probes is allowed (for example for a removal of the impurities of the pads), on the other hand, the lateral force on the wafer is substantially cancelled.

Finally, referring now again to FIG. 2, as previously indicated, the probe head 20 is preferably of the unconstrained vertical type and the second end 21b of the contact probes 21 is adapted to abut onto contact pads 30 of an interposer or space transformer 29.

In particular, the space transformer 29 is adapted to provide a space transformation of the distances between the centres or pitches of the contact pads formed on opposite faces thereof. Still more in particular, on a first face of the space transformer 29 facing the probe head 20, the contact pads 30 can have, with respect to each other, a pitch which is equal to the one of the contact pads 25 of the device under test, while the contact pads (which are not illustrated) formed on a second opposite face of the space transformer 29 have a pitch which is equal to the pitch of contact pads formed on a printed circuit board or PCB (which is also not illustrated) to which said space transformer 29 generally connects; in particular, they have a pitch which is higher with respect to the pitch of the contact pads 30, thereby performing the desired space transformation and allowing an easier arrangement of the contact pads on said second opposite face and an easier connection with the PCB and therefore with the testing apparatus.

The present invention therefore also refers to a probe card for a testing apparatus of electronic devices, comprising at least one probe head 20 according to the present invention, the space transformer 29 adapted to perform a space transformation of the distances between the contact pads 30 formed on the face thereof facing the probe head 20 and/or a PCB adapted to interface said probe card with the testing apparatus.

To conclude, the present invention allows to brilliantly overcome the technical problem, providing the above-mentioned probe head and solving all the drawbacks of the prior art.

Suitably, to sum up the above, at least some holes of the guide (in particular the lower guide) have a non-rectilinear section, that is they are inclined, to force the deformation of the probe as desired in order to control, as desired, the scrub of the contact tips in the most suitable way.

Advantageously, the scrub movement of the contact tips of each probe is therefore precisely controlled.

If the holes are inclined in order to block the scrub (at an angle which is opposite to the angle of scrub, that is, hole with axis which is inclined in a similar way to the axis which connects the centres of the guide holes in which a probe is housed, and therefore somehow corresponding to the inclination of the probe) the lateral forces are applied onto the guide, thus blocking the lateral movement of the contact tip. In this case, the inclination of the holes is opposite with respect to the bending of the probe, and it is this inclination of the hole which controls said bending.

In the case of groups of mirror-like holes (and therefore of corresponding probes), the opposite residual scrubs cancel each other. Thereby, suitably, the overall transversal load exerted by said contact probes onto a device under test and onto the semiconductor wafer which comprises it is substantially zero, that is the force exerted by the probe head which is parallel to a face of the device under test is substantially zero. This allows a more precise and reliable test and avoids phenomena such as the lateral shift of the semiconductor wafer due to the non-compensated (cutting) lateral forces of the contact probes, as it instead happens in the known solutions.

This solution furthermore avoids the probes getting stuck in the guide holes and, as seen, also works in the presence of a movement of the same guide.

It is therefore apparent that the described probe head efficiently solves the technical problem of the present invention, allowing an improved test, especially in the case of several contact probes.

Obviously, a person skilled in the art, in order to satisfy contingent and specific needs, will be able to make numerous modifications and variations to the probe head described above, all included in the scope of protection of the invention as defined by the following claims.

1. A probe head for testing devices under test integrated on a semiconductor wafer, comprising:
a plurality of contact probes comprising a body extending along a longitudinal axis between a first end and a second end, said first end being adapted to contact contact pads of a device under test and said second end being adapted to contact respective contact pads; and
a guide comprising a plurality of guide holes adapted to house a portion of the contact probes, said guide lying in a plane,
wherein the first end and the second end of the contact probes are offset from each other, with reference to the longitudinal axis, along an offset direction thereby defining a scrub direction of said first ends projecting from the respective guide holes,
that wherein the guide comprises guide holes having a pair of opposite walls which are inclined with respect to the longitudinal axis, said guide holes having an axis of symmetry which is not perpendicular with respect to the plane of the guide, defining abutting points against which corresponding opposite walls of said contact probes are adapted to abut, said inclined opposite walls being configured to define, by means of the inclination thereof, a deformation of the contact probes during the contact with the device under test and to control the movement of the portion thereof housed within said guide holes, thereby controlling the movement of the first end of said contact probes in the scrub direction.

2. The probe head according to claim 1, wherein said inclined opposite walls are configured so that, during the contact of the contact probes with the device under test and the bending thereof, said abutting points exert a reaction force which opposes the movement of the portion of the contact probes in the guide holes.

3. The probe head according to claim 2, wherein the inclined opposite walls are configured to cancel or reduce the clearance of the portion of the contact probes in the guide holes, constraining said opposite walls of the contact probes always against the same abutting points.

4. The probe head according to claim 1, wherein said inclined opposite walls are configured so that, during the contact of the contact probes with the device under test and the bending thereof, said inclined opposite walls they are pushed towards abutting points which are opposite the abutting points said inclined opposite walls they are close to in the rest position.

5. The probe head according to claim 4, wherein the inclined opposite walls are configured to increase the clearance of the portion of the contact probes in the guide holes and to guide the movement thereof, and thus to increase the scrub movement of the respective first ends.

6. The probe head according to claim 1, wherein the inclined opposite walls of the guide holes are substantially parallel to each other.

7. The probe head according to claim 1, wherein the guide is a lower guide of the probe head and the guide holes thereof house a lower portion of the contact probes, said lower guide being the guide which is closest to the device under test.

8. The probe head according to claim 7, further comprising an upper guide which is separated from the lower guide by a gap and includes a plurality of guide holes adapted to house a corresponding upper portion of the contact probes, wherein the guide holes of the upper guide are shifted with respect to the guide holes of the lower guide in the offset direction, thereby defining the scrub direction of the first ends of the contact probes.

9. The probe head according to claim 8, wherein the guide holes of the upper guide are provided with opposite walls which are inclined with respect to the longitudinal axis.

10. The probe head according to claim 8, wherein each contact probe has, before the assembly thereof, in the probe head, a non-deformed straight shape, the shift between the guide holes of the lower guide and of the upper guide being apt to cause a deformation of the contact probes resulting in said offset of the ends along the offset direction.

11. The probe head according to claim 1, wherein the offset along the offset direction is substantially equal to 5-30 μm.

12. The probe head according to claim 1, wherein the guide comprises first guide holes, housing a first group of said contact probes, and second guide holes, housing a second group of said contact probes, wherein said first and second guide holes comprise opposite walls which are inclined in a mirror-like manner with respect to the longitudinal axis.

13. The probe head according to claim 12, characterized in that said first guide holes are grouped in a first area of said guide, and said second guide holes are grouped in a second area of said guide, wherein the ends of the contact probes of said first group of contact probes in said first area have an opposed scrub with respect to the ends of the contact probes of said second group of contact probes in said second area, forming distinct areas of the probe head with opposite forces on the semiconductor wafer.

14. A probe card for a testing apparatus of electronic devices, comprising a probe head according to claim 1, a space transformer adapted to perform a space transformation of the distances between contact pads formed on a face thereof facing said probe head, and/or a printed circuit board adapted to interface said probe card with a testing apparatus.
